(19) United States
(12) Patent Application Publication
(10) Pub. No.: US 2011/0162699 A1
(43) Pub. Date: Jul. 7, 2011

(54) SOLAR CELL WITH FUNNEL-LIKE GROOVE STRUCTURE

(75) Inventors: Joseph Shappir, Tel Aviv (IL); Nissim Ben-Yosef, Mevaseret Zion (IL); Uriel Levy, Petach Tikva (IL)

(73) Assignee: SHENKAR COLLEGE OF ENGINEERING AND DESIGN, ROMAT GAN (IL)

(21) Appl. No.: 12/997,790

(22) PCT Filed: Jun. 14, 2009
(86) PCT No.: PCT/IL09/00587

§ 371 Date: Mar. 15, 2011

(30) Foreign Application Priority Data
Jun. 12, 2008 (US) 61061042

(51) Int. Cl. H01L 31/0236; H01L 31/18

(52) U.S. Cl. 136/255; 438/71; 257/E31.13

(57) ABSTRACT

The present invention provides a volumetric solar structure comprising one or more solar cells. The solar structure comprises a semiconductor substrate of a first conductivity type having a patterned surface thereof, the pattern defining an array of spaced-apart grooves of a funnel-like shape, and a second opposite conductivity type material layer positioned on at least a part of the patterned surface of the substrate. The structure thereby defines junction regions, in which charge carriers are generated by incident radiation energy to which the structure is exposed. The junction regions are located at different heights upon the patterned surface of the substrate.

### FIELD OF THE INVENTION

This invention relates to solar cells and to a method of manufacturing thereof.

### BACKGROUND OF THE INVENTION

The use of solar cells, which convert light energy to useful electrical energy, is well known. Light entering these solar cells is absorbed, thereby generating electron-hole pairs, which are then spatially separated by the electric field produced by the solar cell junction and are collected at respective contacts (e.g. top and bottom surfaces) of the solar cell. For example, in an n-p type solar cell, electrons will travel to the top surface where they will then be collected by a metallic grid positioned thereon. Holes, on the other hand, will travel to the bottom surface of the solar cell where they may be collected by a metallic sheet covering the entire bottom surface.

The collection probability describes the probability that a photo-generated carrier absorbed in a certain region of the device will be collected by a p-n junction and therefore contributes to the photo-generated current. The collection probability depends on the distance that a photo-generated carrier must travel compared to the diffusion length and on the surface properties of the device. The collection probability of carriers generated in the depletion region is unity as the electron-hole pair is quickly swept apart by the electric field and are collected. Away from the junction, the collection probability drops. If the carrier is generated at more than a diffusion length away from the junction, then the collection probability of this carrier is quite low. Similarly, if the carrier is generated closer to a region with higher recombination than the junction is, then the carrier will recombine.

Several different types and methods of producing solar cells are known in the industry. An ongoing objective of solar cell manufacturers is to improve the conversion efficiencies of the solar cells in a cost effective manner.

Photons incident on the surface of a semiconductor are either reflected from the top surface, absorbed in the material or, failing either of the above two processes, are transmitted through the material. For photovoltaic devices, reflection and transmission are typically considered as loss mechanisms, because photons which are not absorbed, do not generate electrical power.

The absorption coefficient determines how far into a material, light of a particular wavelength can penetrate before it is absorbed. In a material with a low absorption coefficient, light is poorly absorbed, and if the material is thin enough, it will appear transparent to that wavelength. The absorption coefficient is a characteristic of the material and also depends on the wavelength of light which is being absorbed.

The dependence of absorption coefficient on wavelength causes different wavelengths to penetrate different distances into a semiconductor before most of the light is absorbed. The absorption depth is given by the inverse of the absorption coefficient (i.e. a⁻¹). The absorption depth is a useful parameter which gives the distance into the material at which the light drops to about 36% of its original intensity, or alternately has dropped by a factor of 1/e. Since a given material has a large absorption coefficient for high energy light (small wavelength e.g. blue), the latter is absorbed in a short distance (for silicon solar cells within a few microns) of the surface, while red light spectrum is absorbed less strongly. Even after a few hundred microns, not all near Infrared light is absorbed in silicon.

An ideal solar cell may be modeled by a current source in parallel with a diode. The Shockley ideal diode equation or the diode law is the I-V characteristic of an ideal diode in either forward or reverse bias (or no bias).

The equation is: I_{D}=I_{O}[exp(qV/kT)−1]

where I_{D} is the diode current, I_{O} is the reverse bias saturation current, V is the voltage across the diode, q is the electron's charge, k is Boltzmann's constant, and T is the absolute temperature of the diode junction.

A typical requirement for the solar cells in respect of cost is that a solar cell can be formed on a cheap substrate, like a metal one. On the other hand, silicon is normally used as a semiconductor for making the solar cells. Among others, single-crystal silicon is excellent from the viewpoint of efficiency for converting light energy to electromotive force, i.e. from the viewpoint of photoelectric conversion efficiency. However, single-crystal silicon is relatively expensive. Multi-crystalline silicon is less expensive but yields lower conversion efficiency. Amorphous silicon is even cheaper but yields much lower conversion efficiency.

The conversion efficiency of a solar cell is determined as the fraction of incident power which is converted to electricity and is defined as:

$$η = \frac{{P}_{MAX}}{E * A}$$

wherein P_{MAX} is the maximal output power [W], E the irradiance [W/m²], and A the surface area [m²].

The Quantum Efficiency (QE) is the most commonly used parameter to compare the performance of one solar cell to another. The QE refers the ratio of the number of charge carriers collected by the solar cell to the number of photons of a given energy incident on the solar, cell. QE therefore relates to the response of a solar cell to the various wavelengths in the spectrum of light incident on the cell.

The QE is given as a function of either wavelength or energy. The quantum efficiency ideally has a square shape, where the QE value is unity and constant across the entire spectrum of wavelengths measured. However, the QE for most solar cells is reduced because of the effects of light reflectance and electron-hole recombination, where charge carriers are not able to move into an external circuit. The same mechanisms that affect the collection probability also affect the QE. Because high-energy (blue) light is absorbed very close to the surface, considerable recombination at the front surface affects the “blue” portion of the QE. Similarly, lower energy (red) light is absorbed in the bulk of a solar cell, and a low diffusion length will affect the collection probability from the solar cell bulk, reducing the QE in the red portion of the spectrum. The quantum efficiency can be referred as the collection probability due to the generation profile of a single wavelength, integrated over the device thickness and normalized to the number of incident photons.

Two types of quantum efficiency (QE) of a solar cell are often considered: The external Quantum Efficiency is the ratio of the number of charge carriers collected by the solar cell to the number of photons of a given energy incident on the solar cell. The internal Quantum Efficiency is the ratio between the number of electrons contributing to the electrical current and the number of photo-generated electrons.

Solar cell design involves specifying the parameters of a solar cell structure in order to maximize efficiency, given a certain set of constraints. These constraints are defined by the working environment in which solar cells are produced. For example in a commercial environment where the objective is to produce a competitively priced solar cell, the cost of fabricating a particular solar cell structure must be taken into consideration. However, in a research environment, where the objective is to produce a highly efficient laboratory-type cell, maximizing efficiency rather than cost is the main consideration.

Generally, to maximize the external quantum efficiency of solar cells, it is known to use anti-reflection coatings. The anti-reflection coatings include a thin layer of dielectric material, with a specially chosen thickness so that interference effects in the coating cause the wave, reflected from the anti-reflection coating top surface, to be out of phase with respect to the wave reflected from the semiconductor surfaces. These out-of-phase reflected waves destructively interfere with one another, resulting in zero net reflected energy.

### GENERAL DESCRIPTION

There is a need in the art in providing a high efficiency broad spectrum solar structure, while reducing the cost of the solar structure which is typically associated with a fabrication process, and also simplifying the fabrication process.

Conventional silicon solar cells are not enough efficient and cost effective because of several major reasons:
Single-crystal silicon wafers are too expensive to be used in large area solar cells farms; multi-crystalline silicon based solar cells have currently too low efficiency.
Construction of multi-layer anti-reflecting (AR) coating for maximum sun radiation absorption in the full spectrum of silicon response is too costly. The use of a single-layer anti reflecting coating results in significant reduction of the cell light absorption efficiency thereby contributing into both the internal and external Quantum Efficiencies. As described above, anti-reflective coatings create interference between two reflected waves from the top and bottom of a thin film coating. If these waves are of opposite phase, they will cancel each other and minimize the reflected light. Optimum cancellation occurs when the refractive index of the thin film is tuned for the particular glass used, and the thickness of the thin film is controlled to one-quarter of the targeted wavelength. Given this, it is relatively simple to design an anti-reflective coating for a specific wavelength. However, light from the sun has a broad range of wavelengths and it is desired to use as many of them as possible to generate energy. The traditional solution is to use a multi-layer coating technique, where a combination of many layers produces the desired effect. Besides adding cost, multi-layer coatings will reflect sunlight more than uncoated silicon at certain incident angles. Therefore, conventionally, anti-reflective coatings narrows the wavelength band used by the solar cell around the red spectrum, reducing the quantum efficiency of the solar cell in the blue and near infrared spectrums.

Another problem associated with the use of anti-reflective coating is the decrease of quantum efficiency of the solar cell due to the different position of the sun resulting in different incident light angles. The light reflected from the solar cell depends on the angle at which the light is incident on the surface. Through the course of a day and through the year, the position of the sun changes. As the sun moves across the sky, the incident angle of the sunlight changes, and the amount of reflection increases in the morning and evening hours. Most solar cells are fixed in place and do not track the sun as it moves across the sky. Delivering high anti-reflective performance for solar cell requires the coating to reduce reflections through the whole day when the sun's light is incident from different angles, not just when the sun is overhead. The problem of tracking the sun and of different angles of incidence is also present in solar systems in which solar cells are associated with light concentrators. Generally, to obtain an ohmic contact between the top n- or p-type layer and the metal layer, a heavy doping is applied to the top layer. However, the addition of dopants decreases the charge carrier diffusion length. If the diffusion length is low, the minority carriers recombine instead of being channeled out of the solar cell, and thus are unavailable to generate electricity. Consequently, regions of the solar cell that contact metal are difficult to optimize, as greater dopant concentration increases the efficiency of the metal-semiconductor boundary, but also decreases carrier diffusion length (increasing the surface recombination velocity), reducing the quantum efficiency.
Furthermore, InfraRed (IR) sun radiation is absorbed deep in the silicon away from the shallow junction. As a result, most of the minority carriers generated by the IR radiation do not reach the junction and consequently do not contribute to the internal quantum efficiency of the solar cell. This problem is even more severe in multi-crystalline silicon because the electron diffusion length is much shorter than the electron diffusion length of single-crystal silicon.

Because of these above-mentioned reasons, the quantum efficiency of the conventional silicon based solar cells is limited to about 20% for mono-crystalline (i.e. single-crystal) silicon and about 13% for multi-crystalline silicon.

The present invention enables to overcome the above-mentioned deficiencies and to increase the quantum efficiency of semiconductor-based solar cells (e.g. by a factor of about 1.3). To maximize the cell quantum efficiency, the present invention enables increasing the amount of light collected by the cell that is turned into carriers and increase the collection of photo-generated carriers. While the reduction of reflection is an essential part of achieving a high efficiency solar cell, it is also essential to absorb maximum of the light spectrum in the solar cell. The amount of light absorbed depends on the optical path length and the absorption coefficient. The present invention maximizes the solar energy available for conversion into electricity transmission over the broadband solar spectrum and broad incident angle. The invention uses, for example, low cost standard microelectronic manufacturing technology in semiconductor, to provide a cheap and reliable solar cell structure. Alternatively, the invention may use ink-jet printing techniques.

Therefore, there is provided a volumetric structure comprising one or more solar cells. The solar structure comprises a semiconductor substrate of a first conductivity type having a patterned surface thereof, the pattern defining an array of spaced-apart grooves of a funnel-like shape, and a second opposite conductivity type material layer positioned on at least a part of the patterned surface of the substrate. The structure thereby defines junction regions, in which charge carriers are generated by incident radiation energy to which the structure is exposed. The junction regions are located at different heights upon the patterned surface of the substrate.

In some embodiments, the distance between the different heights defining the depth of the groove is in the range of about 8 μm to about 50 μm.

The grooves arrangement defines the pitch of the grooves pattern. Preferably, the configuration is such that the aspect ratio between the depth of the groove and the pitch of the grooves arrangement is about 1 or higher. However, in some embodiments, the aspect ratio between the depth of the groove and the pitch of the grooves arrangement is about 0.8.

The funnel-like shaped groove has tilted side surfaces extending along at least two intersecting planes, defining multiple interactions of the incident radiation energy with the at least two side surfaces thereby reducing amount of light reflected from the patterned surface, thus increasing external quantum efficiency of the structure.

In some embodiments, the funnel-like shaped groove is formed by a plurality of surfaces comprising horizontal surfaces and the titled side surfaces linking between the horizontal surfaces; the junctions regions being located on the horizontal surfaces in between the tilted side surfaces.

The angle of the tilted side surface may be selected to cause the incident radiation energy from multiple incident angles to be trapped within the structure thereby reducing amount of light reflected from the patterned surface, thus increasing external quantum efficiency of the structure. This also results in the increase of the optical path length of the structure, thus increasing the internal quantum efficiency of the structure.

In some embodiments, the pattern of the grooves, at least some which contain the junction regions, is such that a fill factor of the junction regions within the patterned surface of the structure provides that, for the incident radiation of a given angle of incidence, most of the incident radiation energy is absorbed by the structure through the tilted side surfaces. This enables the absorption of the incident light to be close to the junction regions, and the photo-generation carriers due to red and infrared light spectrum, increasing the internal quantum efficiency probability. This also results in absorption of UV and blue spectrum of the incident radiation in p-type region and not in n+ type region of in which the lifetime of the carrier is lower the diffusion length is lower.

The second material layer may be continuous. In this case, the second material layer has a varying conductivity of the second type (e.g. n++ regions within the n+ layer) thereby defining an array of the spaced-apart junction regions in said continuous layer.

Alternatively, the second material layer is discontinuous defining an array of the spaced-apart junction regions spaced by an insulator layer. The insulator layer may be selected from a silicon oxide layer or and a silicon nitride layer.

Preferably, in one configuration, the junction regions are located at two different heights extending along two substantially parallel planes. In other configuration, the junction regions are located at three different heights extending along three substantially parallel planes.

In some embodiments, the distance between the locally adjacent junction regions is selected such that the majority of red and infrared spectra of the incident radiation energy are absorbed by the surface between them.

In some embodiments, the distance between the locally adjacent junction regions is selected to maximize a number of interactions of the incident radiation with the side surfaces of the groove.

It should be understood that if the light is not absorbed within a diffusion length of the junction, then the photo-generated carriers are lost to recombination. Consequently, by appropriately selecting the distance between junctions arranged in a non-planar configuration (i.e. being located at different heights) such that the optical path is folded such that the entire optical path length is several times the distance between the junctions, the internal quantum efficiency of the device is substantially increased. The length of the optical path (along a line or a curve) in the structure refers to the distance that an unabsorbed photon may travel between the junctions before it escapes out of the structure, therefore a high ratio between the optical path length and the distance between the junctions indicates that light bounces back and forth between the junctions many times (i.e. multiple total internal reflections). Therefore, the present invention enables to use lower grade material (cheaper) with shorter diffusion length and still maintain high quantum efficiency. Furthermore, increasing the doping level of the silicon which indeed reduces the diffusion length, result in higher diode built in voltage and consequently larger generated electromotive power.

Moreover, by changing the angle at which light travels in the solar structure, by having it to be incident on a tilted surface (i.e. sloped profile) enables not only to reduce reflection but also to couple light obliquely into the semiconductor, thus giving a longer optical path length than the distance between the junctions. In particular weakly absorbed red and IR light penetrates the structure diagonally such that photo generation occurs closer to the junction than in conventional planar solar cell structure.

Typically, the angle at which light is refracted into the semiconductor material is, according to Snell's Law, as follows:

n₁ sin θ₁=n₂ sin θ₂

where θ₁ and θ₂ are the angles for the light incident on the interface relative to the normal plane of the interface within the mediums with refractive indices n₁ and n₂ respectively.

If light passes from a high refractive index medium to a low refractive index medium, there is the possibility of total internal reflection (TIR). The angle at which this occurs is the critical angle and is found by setting θ₂ in the above equation to 0.

The present invention uses total internal reflection principles to cause multiple interactions inside the structure. Each groove acts as almost perfect “BLACK BODY” i.e. a minor portion of the incident light is reflected, regardless of the wavelength and angle of incident light.

Moreover, the present invention increases the internal quantum efficiency by minimizing the distance that a photo-carrier (generated in-between the junctions) must travel to reach the closer junction.

In some embodiments, the structure of the present invention may be made with single-crystal silicon substrate or with multi-crystalline silicon substrate. However, it is emphasized that the invention is not limited to silicon material and may be used for any semiconductor material. The second material layer and the substrate may be formed from the same semiconductor substrate that can be different from silicon.

The structure of the present invention may comprise at least one electrode on a non-patterned surface of the semiconductor substrate, and at least one electrode on the patterned surface.

In some embodiments, the structure comprises one or more optical elements exposed to the incident radiation for concentrating the incident radiation energy into the funnel-like grooves. The spaced-apart funnel-like grooves includes the grooves arranged substantially radially upon the patterned surface, the arrangement of groves facing the incident radiation energy.

Moreover, the solar structure of the present invention reduces the requirement of the r any anti-reflection coating.

Therefore, the present invention provides a novel volumetric solar structure having a pattern defining spaced-apart grooves on the semiconductor surface. This pattern, combined with optimized doping profile and contact electrodes allows achieving a 30% increase in quantum efficiency without significant additional costs.

According to another broad aspect of the present invention, there is also provided a method for fabricating a solar structure. The method comprises providing a semiconductor substrate of a first conductivity type, creating at least one sacrificial layer on the semiconductor substrate; creating at least one pattern of spaced apart regions in each of the at least one sacrificial layer, etching the at least one sacrificial layer at a selected etching rate to obtain a desired etching profile, thereby forming a patterned semiconductor surface, the pattern comprising an array of spaced-apart grooves of a funnel-like shape, and creating a second layer of a material of an opposite conductivity type on at least a part of the patterned surface, thereby defining spaced-apart junction regions located at different heights upon the patterned surface, enabling generation of charge carriers within the junction regions by incident radiation energy to which the structure is exposed.

In some embodiments, the pattern creates at least one groove formed by a plurality of surfaces comprising horizontal surfaces and the titled side surfaces linking between the horizontal surfaces; the junctions regions being located on the horizontal surfaces in between the tilted side surfaces.

In some embodiments, the sacrificial layer is selected from thermal oxide layer, PECVD oxide layer, nitride layer or photoresist layer.

The etching may be isotropic or anisotropic.

In some embodiments, the desired etching profile is obtained by etching at a different etching PECVD oxide and thermal oxide; and/or silicon and oxide.

### BRIEF DESCRIPTION OF THE DRAWINGS

In order to understand the invention and to see how it may be implemented in practice, some embodiments will now be described, by way of non-limiting example only, with reference to the accompanying drawings, in which:

FIG. 1 is a schematic representation of a solar structure according to one embodiment of the present invention;

FIGS. 2A-2C are schematic representations of a solar structure according to another embodiment of the present invention;

FIG. 3 represents incident light propagation within the solar structure of FIG. 1;

FIG. 4 represents the incident light propagation within the solar structure of FIG. 2C;

FIG. 5 represents a top view of incident light propagation within the solar cell of FIG. 2C;

FIG. 6 represents a top view of the solar structure of the present invention;

FIGS. 7A-7E illustrates one option of fabrication process of the solar structure of FIG. 1; and;

FIGS. 8A-8H illustrates one option of the fabrication process of the solar structure of FIG. 2C.

### DETAILED DESCRIPTION OF EMBODIMENTS

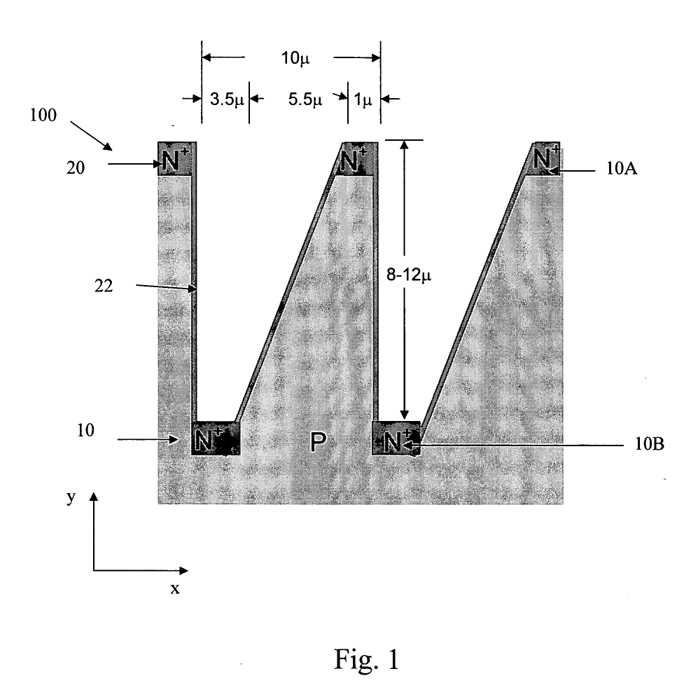

Reference is made to FIG. 1, illustrating a representation of an example of a volumetric structure (i.e. periodic structure) according to one embodiment of the present invention. The solar structure 100 includes a semiconductor substrate 10 of a first conductivity type, silicon of p-type in this specific example, having a patterned surface thereof. The pattern defines an array of spaced-apart grooves of a funnel-like shape (i.e. having tilted side surfaces extending along two intersecting planes), the bottom of the grooves and the top surface (defined by spaces between the grooves) extend along two substantially parallel planes (10A, 10B). On top of the patterned side of the substrate 10, a layer of a second opposite conductivity type material 20 (n+ type conductivity) is positioned, defining p-n junction regions in which charge carriers can be generated by incident radiation energy. In this example, the layer 20 is discontinuous, creating an array of junctions spaced by an insulator 22. The p-n junction regions are located at different heights (10A, 10B) (e.g. top and bottom) upon the patterned side of the substrate, forming a non-planar surface. Two solar cells are illustrated in the figure.

The type of layers' material and the geometry of the structure (i.e. the profile of the structure) are optimized to increase the quantum efficiency of the cell and to assure an optimized light trapping. The incident light propagates toward the funnel-like grooves to be thereafter absorbed or reflected by the solar cell. The light is therefore trapped between the grooves.

It should be noted that the surface recombination velocity is substantially reduced by the appropriate selection of the type of materials used in the solar cell configuration of the present invention. In particular, the combination of a silicon oxide layer and a P+ layer reduces the surface recombination velocity.

In some embodiments, a thin layer of p-type doping of higher concentration than that of the p-type substrate is created in any surface of the cell where there is no n-type layer. This forms a local electric field that pushes the photo-generated electrons away from the silicon surface, where surface generation reduces the electron lifetime and consequently the electron diffusion length.

In this specific and non-limiting example, the dimensions of the solar structure are as follows: the depth of the groove (i.e. difference between the different heights) is in the range of about 8 μm to 12 μm. The n+ type regions have a width of about 1 μm spaced apart by a distance of about 9 μm, such that the pitch of the grooves arrangement is about 10 μm. The aspect ratio between the depth of the groove and the pitch of the grooves arrangement is in the range about 0.8 to 1.2.

It should also be noted that the doping of the substrate is relatively high in the range of about 10¹⁶-10¹⁸ to increase the conversion cell efficiency. The shorter diffusion distances enables to reduce the lifetime of the photo-generated electrons, and therefore higher substrate doping level, leads to a larger voltage applied across the cell, and consequently a larger fraction of the photo-energy is converted into electrical power.

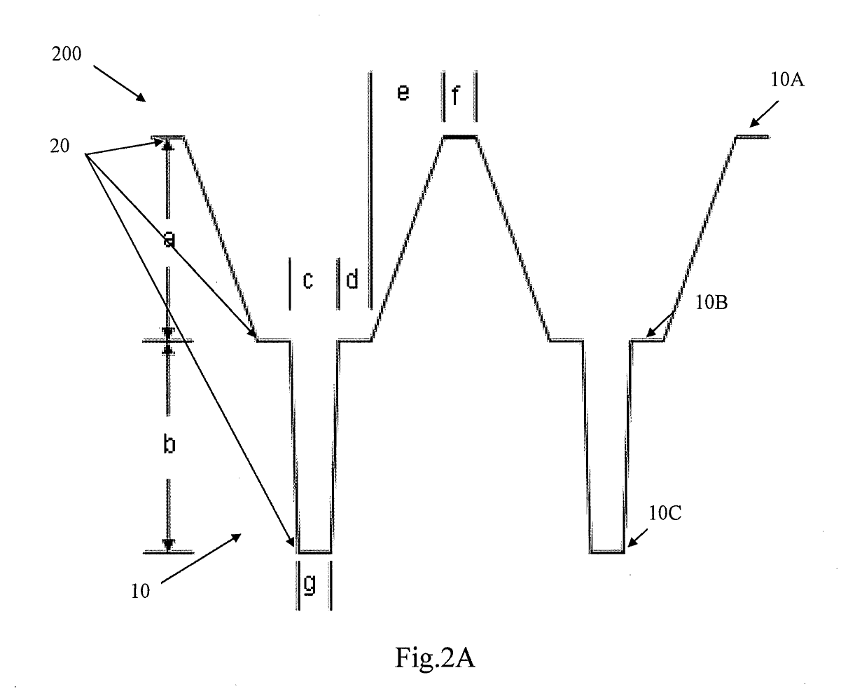

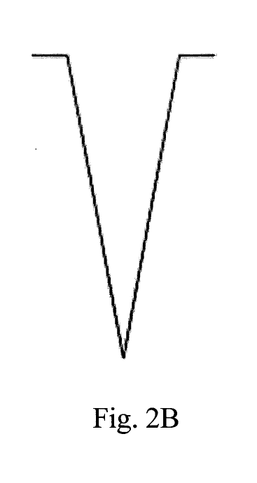

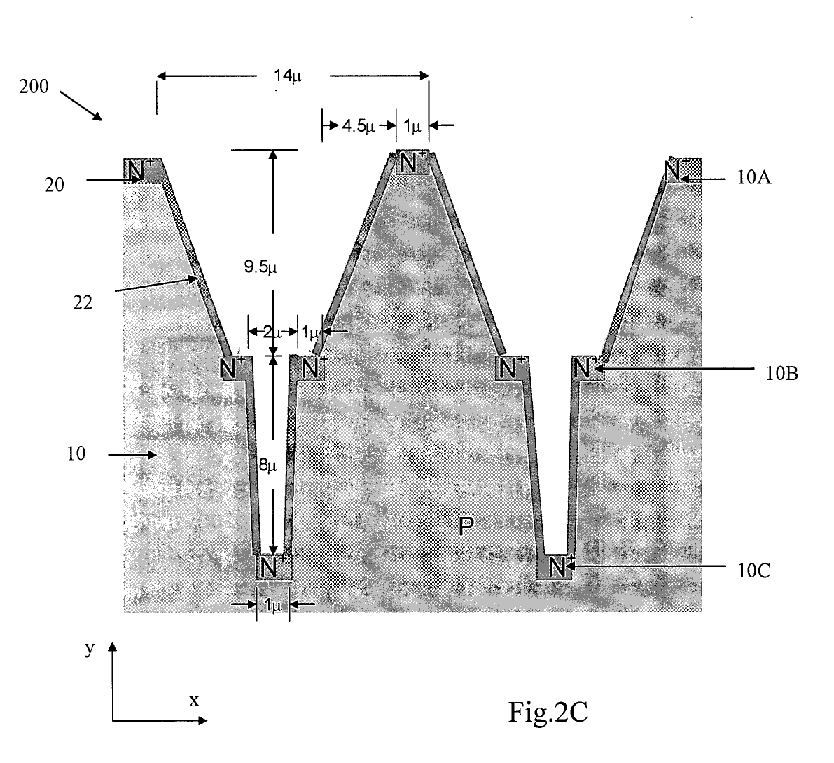

Reference is made to FIG. 2A, illustrating an example of the patterned surface of the semiconductor substrate 10. The patterned semiconductor substrate 10 defines horizontal 20 regions linked by side surfaces. The pattern defines an array (two in this specific case) of spaced-apart grooves of a funnel-like shape extending along three parallel planes located at different heights (10A, 10B, 10C) (e.g. top, middle and bottom). It should be understood that the optimal solar cell structure (i.e. outer profile) depends on certain variable parameters of the substrate material on one hand, and of the solar cell optical design on the other hand. By using standard processing steps, the present invention provides a solar structure in which each of the dimensions a-g can be selected from zero up to several tenths of microns. FIG. 2B illustrates the case in which d and g are equal to zero.

FIG. 2C illustrates the volumetric solar structure 200 formed by the patterned semiconductor substrate 10 of FIG. 2A. The patterned semiconductor substrate 10 is, in this specific example, a silicon substrate of p-type conductivity. The second opposite conductivity type material defines an array of spaced apart n+-type regions 20, positioned on the patterned side of the substrate. In this specific and non-limiting example, the dimensions of the solar cell are as follows: the distance between the two first parallel planes (10A and 10B) is about 9.5 μm and the distance between the two second parallel planes (10B and 10C) is about 8 μm, therefore the depth of the groove is about 17.5. The n+ type regions have a width of about 1 μm. The n+ type regions are spaced apart in the middle level (10B) by a distance of about 2 μm and in the top level (10A) by a distance of about 13 μm, such that the pitch of the grooves arrangement is about 14 μm. The aspect ratio between the depth of the groove and the pitch of the grooves arrangement is 1 or higher, in this specific case, about 1.25.

In an alternative embodiment of the invention, the n+ type region cover larger fraction of the groove surface up to the entire surface (e.g. a continuous n+ surface layer of the patterned structure). In this case, n++ regions are provided (by doping) on the bottom of the groove and within the spaces between the grooves.

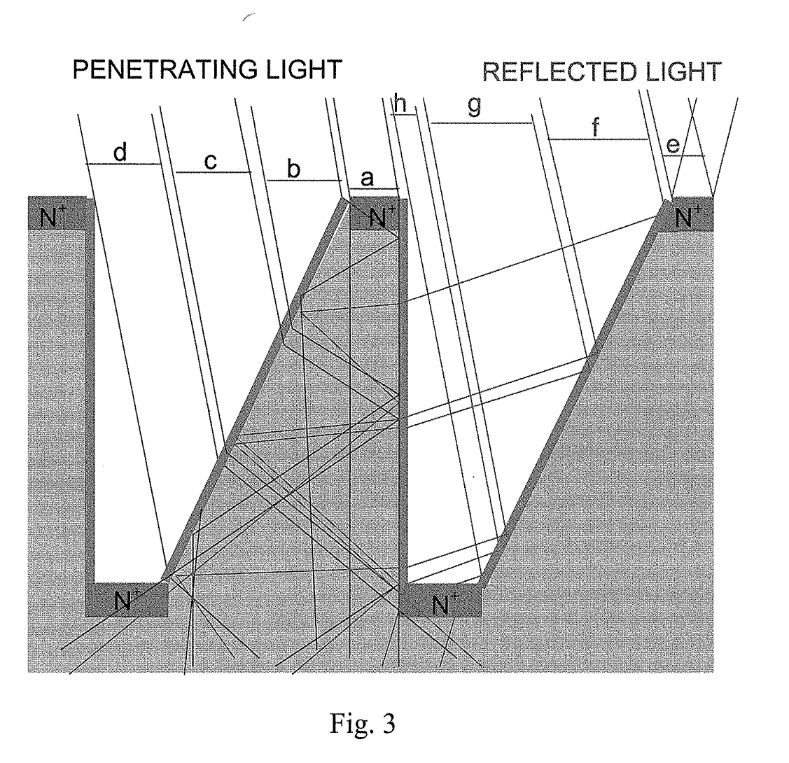

Reference is made to FIG. 3 illustrating the incident light propagation within the solar structure of FIG. 1 for a given ray interfacing the solar cell at a given incident angle. The rays a-h illustrates the possible propagations (i.e. transmission and reflection) with the cell. If a-d illustrate the transmitted propagation, it can be observed that rays a and b are first absorbed by the solar cell propagate perpendicularly to the cell surface but they pass more than 12 μm before reaching the vicinity of the bottom junction, c and d propagate diagonally to the cell surface. If e-h illustrate the reflected propagation, it can be observed that e is lost, f and g are reflected diagonally but penetrates into the adjacent solar cell after passing more than 12 μm before they reach the vicinity of the bottom junction, and h propagates vertically to the solar cell and can be absorbed in the bottom cell or in the bottom cell of the adjacent solar cell.

By using the configuration of the present invention, the photo-generated carrier generated between the junctions have to travel only about 6-7 μm to reach a junction, thus minimizing the recombination rate. Moreover, the rays have travel between 10 μm and 20 μm within the cell before they reach the vicinity of the bottom junction, increasing the collection probability and the quantum efficiency.

Furthermore, by using the solar structure of the present invention, the lost associated with reflected light rays (ray e) occurs only on about 15% of the total area of the solar cell, e.g. about two microns of horizontal plane out of about 14 microns of the pitch of the grooves arrangement. Another advantage of the present configuration is that weakly absorbed red and IR light penetrated into the semiconductor substrate diagonally, such that the photo generation occurs in the vicinity of the junction, increasing the collection probability.

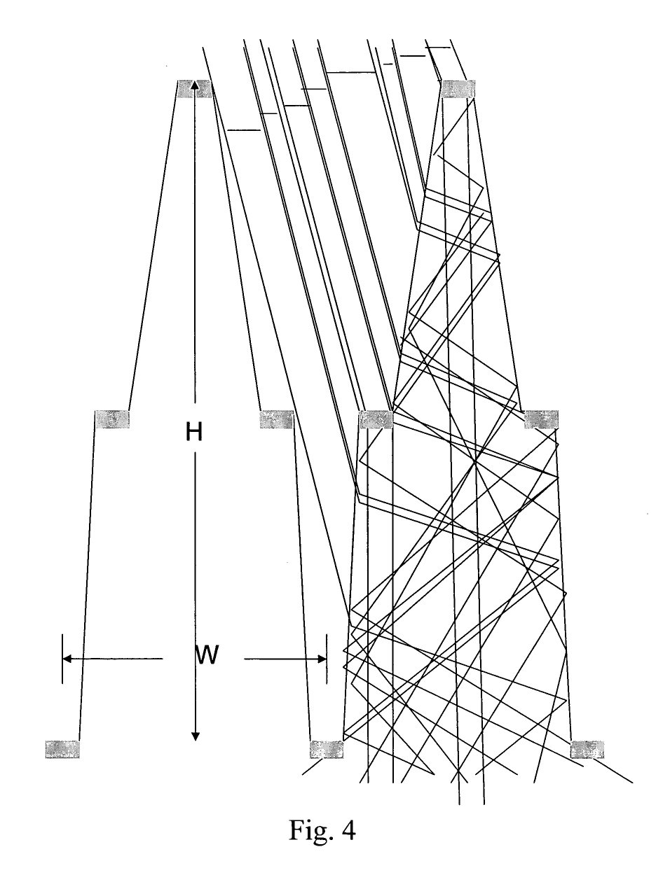

Reference is made to FIG. 4 illustrating the incident light propagation within the solar structure of FIG. 2C for a given ray interfacing the solar cell at a given incident angle. The rays tracing illustrates the possible propagations (i.e. transmission and reflection) within the cell. The optimized geometry of the cell is selected such that the quantum efficiency is maximal by configuring the cell such that all rays penetrate between 10 μm and 20 μm within the cell before they reach the vicinity of the bottom junction. Moreover, the dependence of absorption coefficient on wavelength causes different wavelengths to penetrate different distances (i.e. different absorption depths) into a semiconductor before most of the light is absorbed. In the present invention, about 75% of the incident light does not enter the cell through the top junction (i.e. heavily doped region) but through the sidewalls, such that the UV and blue spectrum also contributes to the quantum efficiency. Furthermore, most rays penetrate the substrate diagonally and are thus absorbed close to the junctions minimizing the recombination rate. Because of the short collecting distances (i.e. the absorption of the incident light occurs close to the junction regions) provided by the solar cell configuration of the present invention, the lifetime of the photo-generated carriers can be shorter, leading to the efficient use of multi-crystalline silicon as the semiconductor substrate in which the electron diffusion length is shorter than the electron diffusion length of a single-crystal silicon.

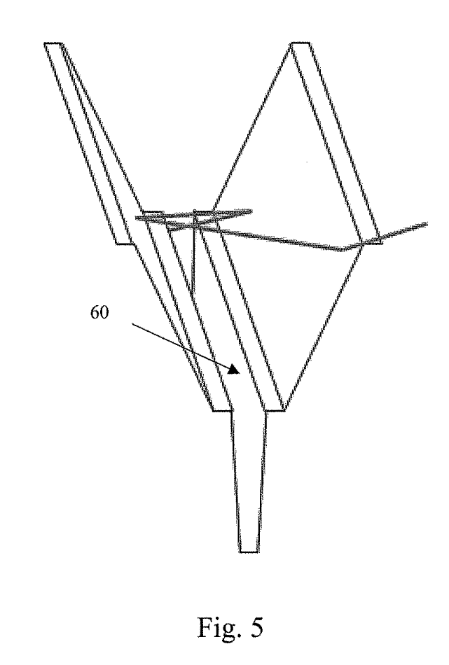

Reference is made to FIG. 5 illustrating a top view of a ray tracing propagation within a solar cell of the present invention. The ray is reflected along the funnel-like groove 60 until it penetrates the substrate in the vicinity of the bottom junction region. By using this type of configuration, the external quantum efficiency is increased and the lost of reflected light rays is minimized (about 15% of the total area of the solar cell).

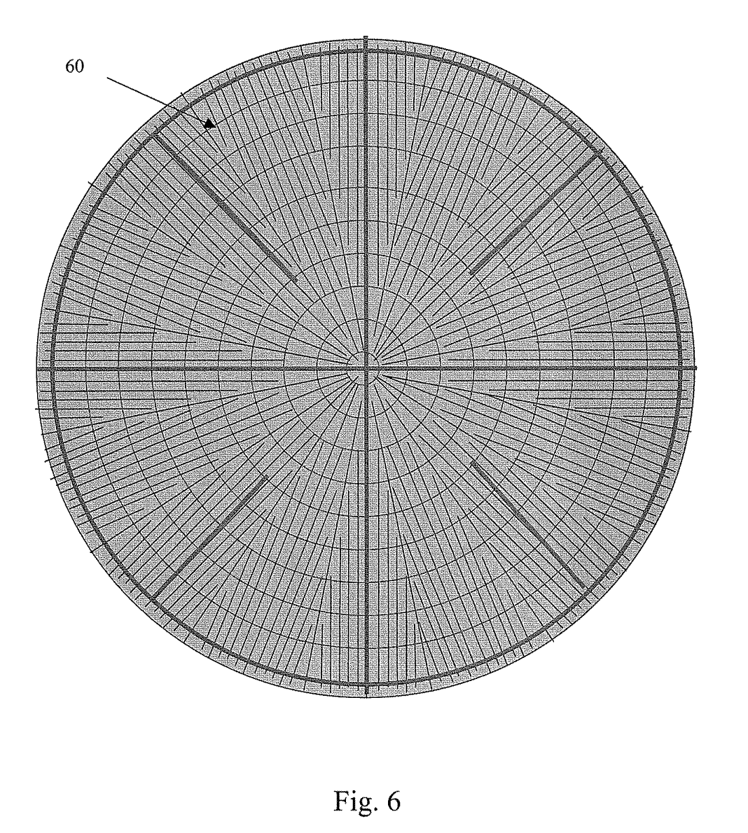

Reference is made to FIG. 6 illustrating a top view (radial configuration) of the solar structure of the present invention. As illustrated in the figure, in the radial configuration, the funnel-like grooves 60 are represented by lines arranged radially to the semiconductor surface.

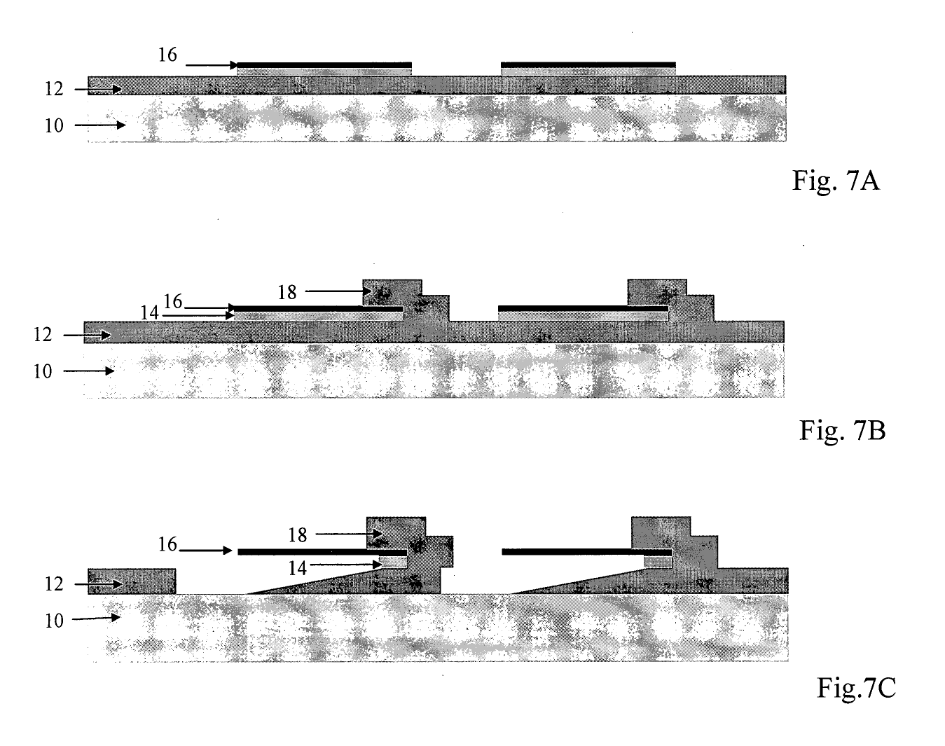

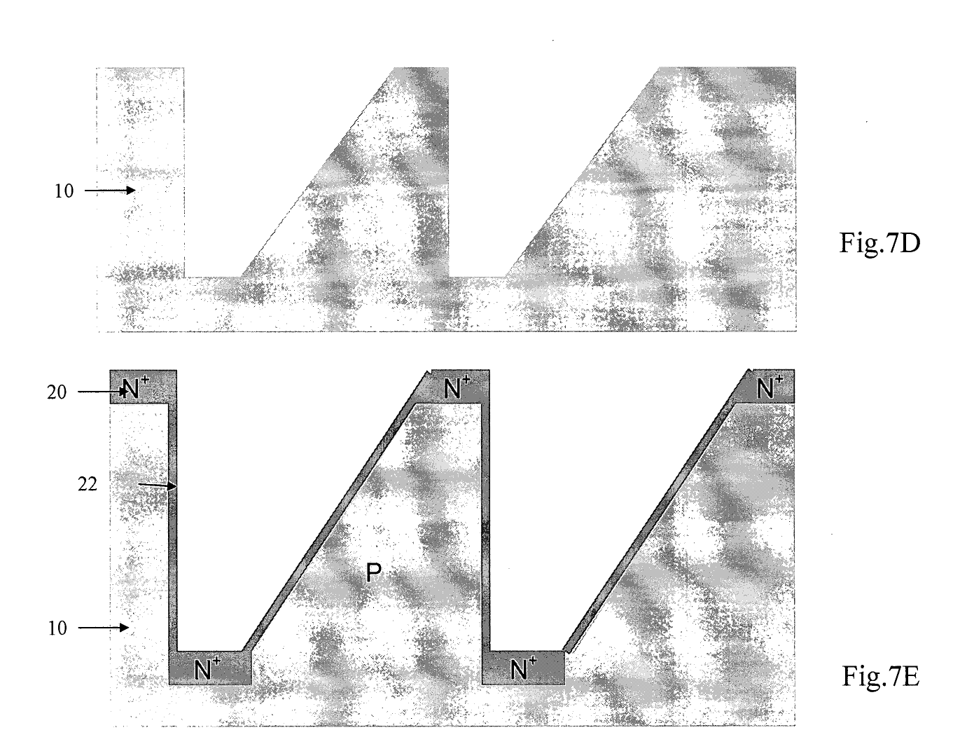

Reference is made to FIG. 7A illustrating the fabrication process of a solar structure, according to one embodiment. The solar structure of the present invention is provided by providing a semiconductor substrate of one conductivity type, creating at least one sacrificial layer onto a semiconductor substrate; creating a pattern of spaced apart regions of the sacrificial layer; etching at least one sacrificial layer at a selected etching rate to obtain a desired etching profile; obtaining a semiconductor substrate having a sloped funnel-like surface; and creating an array of spaced-apart solid material of a different conductivity type positioned on selected regions of the sloped funnel-like substrate, to thereby obtain a solar structure. In this specific and non-limiting example, the fabrication of the solar structure begins with a starting material of a p-type silicon wafer 10. The silicon wafer 10 may be a single-crystal silicon wafer or a multi-crystalline silicon wafer. Then, a thermal oxidation step grows an approximately 0.8 μm thick silicon thermal oxide layer 12 over the silicon wafer 10. A layer of oxide 14 of a thickness of approximately 100 nm is deposited on the silicon thermal oxide layer 12, using plasma enhanced chemical vapor deposition (PECVD) techniques. A layer of nitride 16 of a thickness of approximately 50 nm is deposited on the PECVD silicon oxide layer 14, using plasma enhanced chemical vapor deposition (PECVD) techniques. A first patterned mask layer (e.g. resist) is then formed by conventional lithography or by any other patterning technique such as ink jet printing, defining spaced apart regions having a width of about 7 μm or more and spaced by a distance of about 3 μm or more.

An etching process is applied to the exposed regions of the nitride layer 16 and of the PECVD oxide layer 14 through the patterned mask layer acting as an etching mask. The patterned mask layer is then removed.

As illustrated in FIG. 7B, a second patterned mask layer 18 (e.g. resist) is then formed by lithography or by any other conventional patterning techniques, defining spaced apart regions covering a portion on top of the nitride layer 16 and a portion of the spaces defined by the first pattern.

As illustrated in FIG. 7C, a buffered wet oxide etch is then performed (Buffered HF) through the nitride layer 16 to remove a part of the PECVD silicon oxide layer 14 and a part of the silicon oxide layer 12. It should be noted that the Buffered HF is selected such that the etching selectivity ratio between the PECVD oxide etch rate versus the thermal oxide etch rate is about 6.7:1, such that a sidewall of layer 12 is sloped etched (i.e. sloped profile). It should be understood that the use of wet etching techniques enables to remove the thermal oxide film and the PECVD layer at a different etching rate to obtain a desired etching profile. Since the wet etch performed reduces the film thickness of the exposed thermal oxide in proportion to the etch rate ratio, the initial thickness of the deposited oxide was adjusted accordingly. The mask layer 18 is then removed as illustrated in FIG. 7D. A wet nitride etch is then applied to remove layer 16. A selective etching (RIE) is then applied to the thermal oxide layer 12 and to the silicon layer 10 such that the etching selectivity ratio between silicon and thermal oxide is 10:1 obtaining a sloped etching of the sidewall of silicon layer 10 (sloped profile). Similarly than the use of the wet etching techniques, the RIE technique enables to remove the thermal oxide film and the silicon layer at a different etching rate to obtain a desired etching profile.

A short isotropic wet etch is then applied to clear the entire silicon surface. P+ type diffusion is applied to form a skin layer responsible for the formation of the built in electric field, which repels the photo-generated electrons away from the silicon surface. A thermal oxidation step is then applied to grow a continuous oxide layer 22 of about 300 nm. A further RIE step is applied to etch the horizontal areas of the continuous oxide layer 22 (i.e. top and bottom surfaces) leaving oxide on the tilted side and vertical surfaces. N+ doping is then applied and affects the exposed horizontal areas, to form regions 20 by phosphor or arsenic diffusion from either gas phase or deposited doped oxide, forming an n+-p junction. Optionally, an anti-reflecting nitride layer is then deposited. A metallization is then performed on the front side of the wafer as commonly performed in the art, followed by aluminum evaporation on the backside of the silicon wafer. It should be noted that by heavily doping the n-type region (n+) next to a metal region helps to form an ohmic (low-resistance) contact through quantum tunneling and/or thermally assisted tunneling.

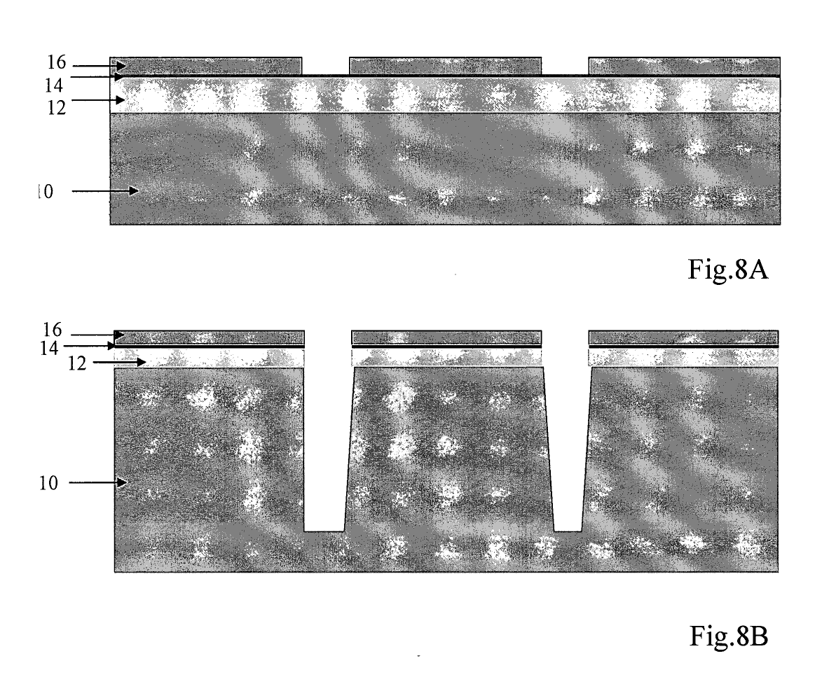

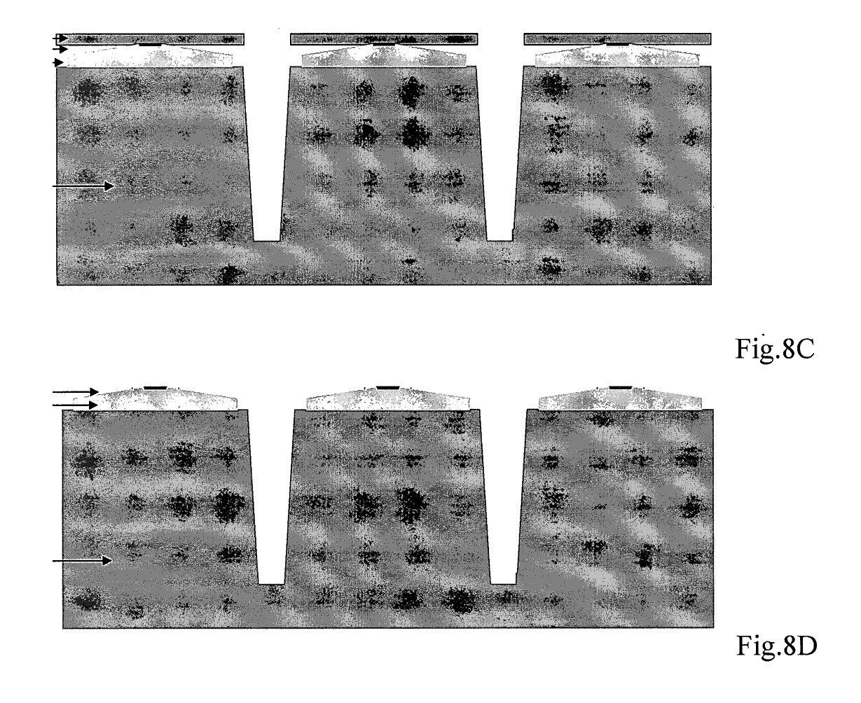

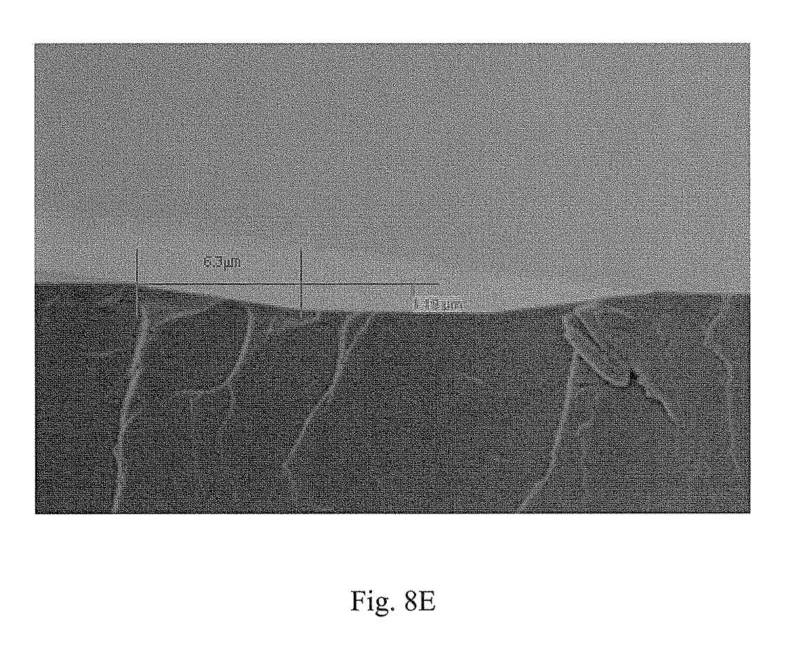

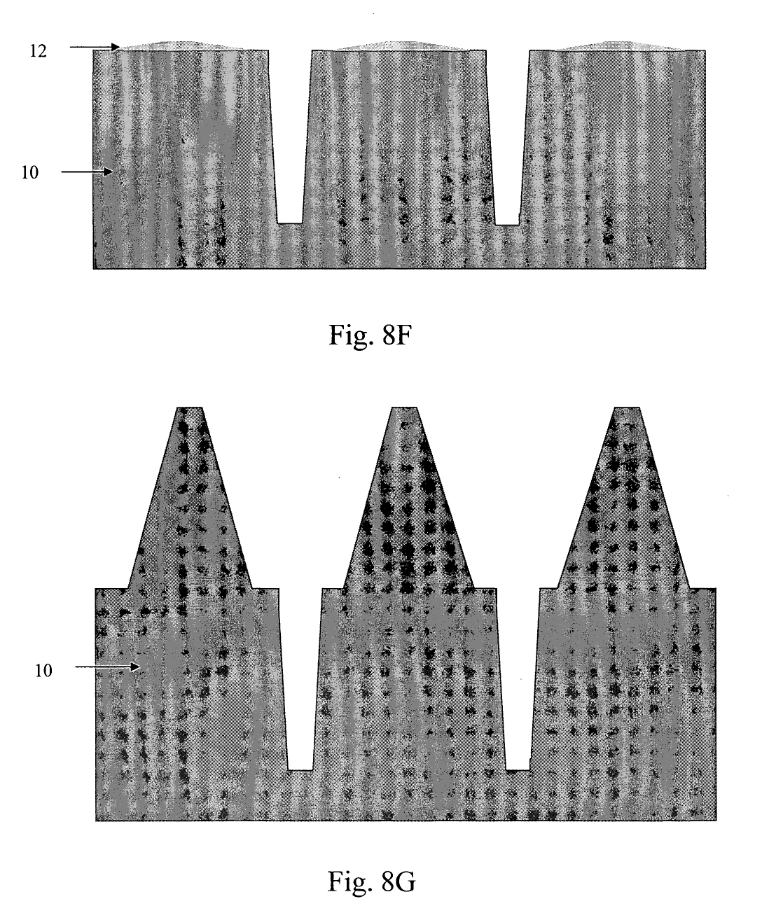

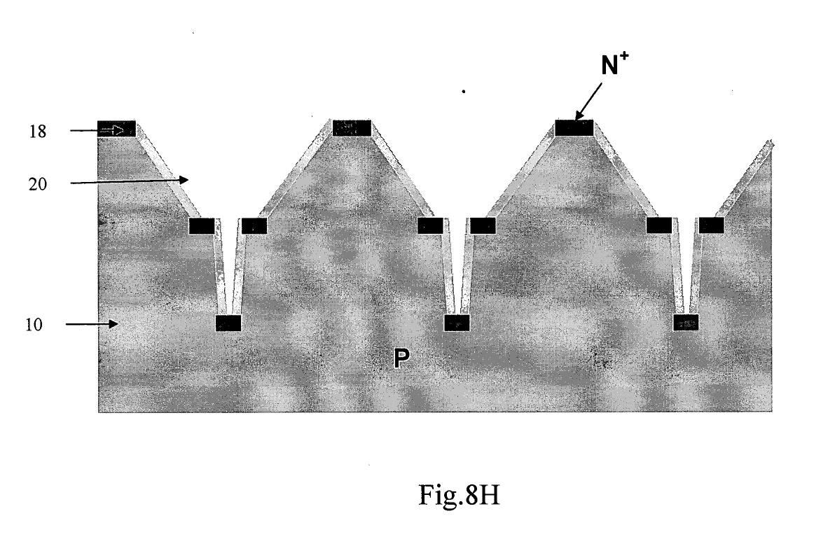

Reference is made to FIG. 8A illustrating the fabrication process of a solar structure according to another embodiment. In this specific and non-limiting example, the fabrication of the solar structure begins with a starting material of a p-type silicon wafer 10. The silicon wafer 10 may be a single-crystal silicon wafer or a multi-crystalline silicon wafer. Then, a thermal oxidation step grows an approximately 1 μm thick silicon thermal oxide layer 12 over the silicon wafer 10. A layer of oxide 14 of a thickness of approximately 100 nm is deposited on the silicon thermal oxide layer 12, using plasma enhanced chemical vapor deposition (PECVD) techniques. A patterned mask layer (e.g. resist) 16 is then formed by lithography or by any other patterning technique such as ink jet printing, defining spaced apart regions having a width of about 2 μm or more and spaced by a distance of about 12 μm or more.

As illustrated in FIG. 8B, a first Reactive Ion Etching (RIE) etches the exposed regions of the thermal oxide 12 and of the PECVD oxide 14 is applied through the patterned mask layer 16 acting as an etching mask. A second Reactive Ion Etching (RIE) etching the exposed regions of the silicon wafer 10 is then applied through the patterned mask layer 16 acting as an etching mask to create spaced apart grooves having a height of about 10 μm in the silicon wafer 10.

A wet oxide etch is then applied to the thermal oxide layer 12 and to the PECVD oxide 14 such that the etching selectivity ratio between PECVD-Oxide and thermal oxide is 6.7:1 obtaining an sloped etching of the sidewall of layers 12 and 14. It should be understood that the use of wet etching techniques enables to remove the thermal oxide film and the PECVD layer at a different etching rate to obtain a desired etching profile. Since the wet etch performed reduces the film thickness of the exposed thermal oxide in proportion to the etch rate ratio, the initial thickness of the deposited oxide was adjusted accordingly. The mask layer 16 is then removed as illustrated in FIG. 8D.

The oxide sloped profile obtained by the wet etching step is illustrated in FIG. 8E, in which the measured slope is about 6.3 μm.

A RIE step is applied etching about 0.5 μm of the thermal oxide layer 14, as illustrated in FIG. 8F.

As illustrated in FIG. 8G a selective etching is then applied to the thermal oxide layer 12 and to the silicon layer 10 such that the etching selectivity ratio between silicon and thermal oxide is 19:1 obtaining sloped etching of the sidewall of silicon layer 10. The etched thickness of the thermal oxide 12 is about 0.5 μm, while the etched thickness of the silicon layer 10 is about 9.5 μm.

As illustrated in FIG. 8I, a p+ type (e.g. boron) diffusion step is applied to the structure. The boron concentration may be about 10¹⁷-10¹⁸ cm⁻³. As described above, the p+ type diffusion is applied to form the p+ skin layer responsible for the formation of the electric field, which repels the photo generated electrons away from the silicon surface. A wet oxidation step is then applied to grow a continuous oxide layer 20 of about 0.8 μm. A further RIE step is applied to etch the horizontal areas of the continuous oxide layer 20. n+ doping is then applied and affects the exposed horizontal areas, to form the junction n+ region by gas phase or from doped deposited oxide containing phosphor or arsenic forming an n+-p junction. A metallization is then performed on the front side of the wafer as commonly performed in the art, followed by aluminum evaporation on the backside of the silicon wafer. It should be noted that by heavily doping the n-type region (n+) next to a metal region helps to form an ohmic (low-resistance) contact through quantum tunneling and/or thermally assisted tunneling.

Furthermore, since most of the radiation enters the cell not through the junctions regions (n+ regions) but inside the grooves (i.e. through the tilted side surfaces of the structure), the doping level and the diffusion length of the junction regions may be significantly larger than when a continuous second material layer is used (continuous n+ layer). This in turn, results in lower series resistance of the second material layer (n+ layer) thus enabling the increase in the distance between adjacent contact electrodes (e.g. adjacent metal lines). Therefore, a smaller fraction of the structure area is covered by metal, further increasing the structure external quantum efficiency.

1-40. (canceled)

41. A volumetric structure comprising one or more solar cells, the structure comprising a semiconductor substrate of a first conductivity type having a patterned surface thereof, the pattern defining an array of substantially parallel spaced-apart grooves of a funnel-like shape, and a second opposite conductivity type material layer positioned on at least a part of the patterned surface of the substrate, the structure thereby defining an array of junction regions in which charge carriers are generated by incident radiation energy to which the structure is exposed, said junction regions being located at different heights upon the patterned surface of the substrate, wherein said second opposite conductivity type material layer has one of the following configurations: (i) is continuous and has a varying conductivity of said second type defining said array of the junction regions; and (ii) is discontinuous defining said array of spaced-apart junction regions.

42. The structure of claim 41, wherein an aspect ratio between a depth of the groove and a pitch of the grooves arrangement is about 1 or higher.

43. The structure of claim 41, wherein a distance between the different heights defining a depth of the groove is in the range of about 8 μm to about 50 μm.

44. The structure of claim 41, wherein the funnel-like shaped groove has tilted side surfaces extending along at least two intersecting planes, defining multiple interactions of the incident radiation energy with said at least two side surfaces thereby reducing amount of light reflected from the patterned surface, thus increasing external quantum efficiency of the structure.

45. The structure of claim 44, wherein the funnel-like shaped groove is formed by a plurality of surfaces comprising horizontal surfaces and said titled side surfaces linking between said horizontal surfaces; the junctions regions being located on said horizontal surfaces in between said tilted side surfaces.

46. The structure of claim 44, wherein an angle of the tilted side surface is selected to cause the incident radiation energy from multiple incident angles to be trapped within the structure thereby reducing amount of light reflected from the patterned surface as well as resulting in increasing of the optical path length of the structure, thus increasing external and internal quantum efficiency of the structure respectively.

47. The structure of claim 44, wherein the pattern of the grooves, at least some which contain the junction regions, is such that a fill factor of the junction regions within the patterned surface of the structure provides that for the incident radiation of a given angle of incidence, most of the incident radiation energy is absorbed by the structure through the tilted side surfaces, resulting in absorption of UV and blue spectrum of the incident radiation, as well as enabling the absorption of the incident red and infrared light to be close to the junction regions thus, increasing the internal quantum efficiency.

48. The structure of claim 41, wherein said junction regions are located at two or three different heights extending along two or substantially parallel planes respectively.

49. The structure of claim 41, wherein a distance between the locally adjacent junction regions is selected to achieve at least one of the following conditions: the majority of red and infrared spectra of the incident radiation energy is absorbed by the surface between the locally adjacent junction regions, and a number of interactions of the incident radiation with the side surfaces of the groove is maximized.

50. The structure of claim 41, wherein said semiconductor substrate is a silicon substrate being a multi-crystalline substrate or a single-crystal substrate.

51. The structure of claim 41, wherein said second material layer and the substrate are formed from the same semiconductor substrate.

52. The structure claim 41, comprising at least one electrode on a non-patterned surface of the semiconductor substrate, and at least one electrode on said patterned surface.

53. The structure of claim 41, comprising one or more optical elements exposed to the incident radiation for concentrating the incident radiation energy into the funnel-like grooves.

54. The structure of claim 53, wherein said spaced-apart substantially parallel funnel-like grooves includes the grooves arranged substantially radially upon the patterned surface, the arrangement of groves facing the incident radiation energy.

55. A method for fabricating a solar structure, the method comprising: providing a semiconductor substrate of a first conductivity type, creating at least one sacrificial layer on the semiconductor substrate; creating at least one pattern of spaced apart regions in each of said at least one sacrificial layer, etching said at least one sacrificial layer at a selected etching rate to obtain a desired etching profile, thereby forming a patterned semiconductor surface, said pattern comprising an array of spaced-apart grooves of a funnel-like shape, and creating a second layer of a material of an opposite conductivity type on at least a part of the patterned surface, said second opposite conductivity type material layer having one of the following configurations: (i) is continuous and has a varying conductivity of said second type defining said array of the spaced-apart junction regions; and (ii) is discontinuous defining said array of the spaced-apart junction regions, thereby defining spaced-apart junction regions located at different heights upon said patterned surface, enabling generation of charge carriers within the junction regions by incident radiation energy to which the structure is exposed.

56. The method of claim 55, wherein said pattern creates at least one groove formed by a plurality of surfaces comprising horizontal surfaces and said titled side surfaces linking between said horizontal surfaces; the junctions regions being located on said horizontal surfaces in between said tilted side surfaces.

57. The method of claim 55, wherein said junction regions are located at two or three different heights extending along two or three substantially parallel planes respectively.

58. The method of claim 55, wherein said second material layer and the substrate are formed from the same semiconductor substrate.

59. The method of claim 55, wherein said semiconductor substrate is a silicon substrate being a multi-crystalline substrate or a single-crystal substrate.

60. The method of claim 55, wherein said sacrificial layer is selected from at least one of thermal oxide layer, PECVD oxide layer, nitride layer, photoresist layer.

61. The method of claim 55, wherein said etching is isotropic or anisotropic.

62. The method of claim 55, wherein said desired etching profile is obtained by etching at a different etching at least one of the following materials PECVD oxide with thermal oxide, and silicon with oxide.

63. The method of claim 55, wherein said desired etching profile is obtained by a plurality of RIE processes.
